(19) United States
(12) Patent Application Publication
(10) Pub. No.: US 2008/0073794 A1
(43) Pub. Date: Mar. 27, 2008

(54) SEMICONDUCTOR APPARATUS AND FABRICATION METHOD THEREOF

(75) Inventors: Susumu Obata, Yokohama-shi (JP); Izuru Komatsu, Yokohama-shi (JP); Tomohiro Iguchi, Kawasaki-shi (JP); Tomoyuki Kitani, Yokohama-shi (JP); Masako Hirahara, Yokohama-shi (JP); Yasunari Ukita, Yokohama-shi (JP); Kazuhito Higuchi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/854,187

(22) Filed: Sep. 12, 2007

(30) Foreign Application Priority Data
Sep. 25, 2006 (JP) 2006-258930

(51) Int. Cl. H01L 23/48; H01L 21/4763

(52) U.S. Cl. 257/773; 438/652; 257/E23.01; 257/E21.495

(57) ABSTRACT

A semiconductor device (3) is provided with a first electrode (A), a lead (4) has a second electrode (B), and a metallic film (6) electrically interconnects the first electrode (A) and the second electrode (B), allowing for a more reduced internal resistance, high reliability, and facilitated fabrication.

### CROSS REFERENCE TO RELATED APPLICATION

The present application claims the benefit of priority under 35 U.S.C §119 to Japanese Patent Application No.2006-258930, filed on, Sep. 25, 2006, of which the contents are incorporated herein by reference.

### BACKGROUND OF THE INVENTION

1. Field of Art

The present invention relates to a semiconductor apparatus and a fabrication method thereof, and particularly, to a semiconductor apparatus having a current conducting member with a reduced resistance between an electrode of a semiconductor device and an electrode of a lead, and to a fabrication method of the same.

2. Description of Related Art

Semiconductor markets have recent demands for a semiconductor apparatus adapted for a high-level processing ability and high-speed actions, affording low power consumption when working. In order to overcome such two contrary objects, they push advancing miniaturization of circuitry for semiconductor apparatuses, and reducing an entirety of internal resistances (e.g. on-resistances) of semiconductor apparatus for efficient use of supplied power.

As an example of the semiconductor apparatus, one may take a transistor package including an FET (field effect transistor) employed for a current switching or amplification. In such a transistor package, a semiconductor device has a set of electrodes provided thereon and a set of lead electrodes disposed in correspondence thereto, and the sets of electrodes are interconnected by a plurality of wires made of a conductive metal, such as gold (Au) or aluminum (Al).

Such a semiconductor apparatus has as internal resistances thereof current conducting members interconnecting electrodes of a semiconductor device and electrodes of leads. Typically, such current conducting members are composed of metallic wires that have significant resistances relative to an entire internal resistance of the semiconductor apparatus. To this point, even in use of metallic wires, they may have reduced contact resistances, thereby rendering low an entirety of connection resistances between electrodes of the semiconductor device and electrodes of the leads.

For this arrangement, metallic wires may, for example, be enlarged in diameter or increased in number, with an increased tendency for neighboring metallic wires to be shunted or with a greater restriction to the number of wires to be installed or the installation space, constituting a technical difficulty. On the other hand, the metallic wires may have their own resistances reduced by using the method of altering a metallic material of the metallic wires to such one that has a lower resistance than gold (Au) or aluminum (Al). However, this method restricts the kind of employable metal, and may unsuccessfully have high-reliable joints, thus constituting a difficulty in the use.

As a measure to solve such a problem, Japanese Patent Application Laying-Open Publication No. 2002-314018 (referred herein to “JP 2002-314018 A”) has disclosed a semiconductor apparatus in which, for an entirety of resistances of the apparatus to be reduced, planer conductive metallic members are used for electrical connections between electrodes of a semiconductor device and electrodes of associated leads. This semiconductor apparatus has increased sectional areas of current conduction paths between the electrodes of semiconductor device and the electrodes of leads, with resultant reduction in resistances between semiconductor device and leads. In this semiconductor apparatus, aluminum (Al) that tends to be plastically deformed is employed to the planer metallic members, and ultrasonic waves are used to form their metallic joints to the electrodes of semiconductor device and to the electrodes of leads.

### SUMMARY OF INVENTION

The arrangement disclosed in JP 2002-314018 A requires imposition of a severe load for ultrasonic formation of joints of the planer members made of aluminum (Al). This arrangement needs the imposed load to be born by the semiconductor device itself, and is inapplicable to such a semiconductor device that has a smaller size than prescribed, or that is unable to bear severe loads. Still less, it is difficult for the planer members made of aluminum (Al) to have greatly reduced resistances.

To avoid such disadvantages, there may be an arrangement using a conductive paste or solder at locations where planer metallic members are electrically connected to electrodes of a semiconductor device and electrodes of leads. However, the conductive paste as well as the solder has a relatively low durability to temperature variations. In particular, at joints subjected to a cyclic temperature test involving violent temperature differences or sudden temperature changes, the conductive paste or solder in use may crack or get brittle.

The present invention has been devised in view of the foregoing points. It therefore is an object of the present invention to provide a semiconductor apparatus and a fabrication method thereof allowing for a more reduced internal resistance, high reliability, and facilitated fabrication.

To achieve the object, according to an aspect of the present invention, a semiconductor apparatus comprises a semiconductor device provided with a first electrode, a lead having a second electrode, and a metallic film electrically interconnecting the first electrode and the second electrode.

According to another aspect of the present invention, a fabrication method of a semiconductor apparatus comprises the steps of filling a resin between a first electrode provided on a semiconductor device and a lead having a second electrode, and providing a metallic film electrically interconnecting the first electrode and the second electrode, with the filled resin in between.

According to another aspect of the present invention, a fabrication method of a semiconductor apparatus comprises the steps of filling a resin between a first electrode provided on a semiconductor device and a lead having a second electrode, removing filled resin parts on the semiconductor device and the lead, having the first electrode and the second electrode exposed respectively; and providing a metallic film electrically interconnecting the first electrode and the second electrode, with a filled rein part in between.

According to any one of the foregoing aspects of the present invention, a semiconductor apparatus or a fabrication method thereof is adapted to allow for a more reduced internal resistance, high reliability, and facilitated fabrication.

### BRIEF DESCRIPTION OF THE ACCOMPANYING DRAWINGS

FIG. 1 is a perspective view of a semiconductor apparatus according to a first embodiment of the present invention.

FIG. 2 is a sectional view along line X-X of FIG. 3 of the semiconductor apparatus according to the first embodiment.

FIG. 3 is a sectional view along line Y-Y of FIG. 2 of the semiconductor apparatus according to the first embodiment.

FIG. 4 is a sectional view of a work describing a fabrication method of the semiconductor apparatus according to the first embodiment.

FIG. 5 is a sectional view of a work describing the fabrication method of the semiconductor apparatus according to the first embodiment.

FIG. 6 is a sectional view of a work describing the fabrication method of the semiconductor apparatus according to the first embodiment.

FIG. 7 is a sectional view of a work describing the fabrication method of the semiconductor apparatus according to the first embodiment.

FIG. 8 is a sectional view of a work describing the fabrication method of the semiconductor apparatus according to the first embodiment.

FIG. 9 is a sectional view of a semiconductor apparatus according to a second embodiment of the present invention.

FIG. 10 is a sectional view of a work describing a fabrication method of a semiconductor apparatus according to a third embodiment of the present invention.

FIG. 11 is a sectional view of a work describing the fabrication method of the semiconductor apparatus according to the third embodiment.

FIG. 12 is a sectional view of a work describing the fabrication method of the semiconductor apparatus according to the third embodiment.

FIG. 13 is a sectional view of a work describing the fabrication method of the semiconductor apparatus according to the third embodiment.

FIG. 14 is a sectional view of the semiconductor apparatus according to the third embodiment.

### DETAILED DESCRIPTION OF THE PREFERRED EMBODIMENTS

There will be detailed the preferred embodiments of the present invention, with reference to the accompanying drawings.

### First Embodiment

Description is now made of configuration of a semiconductor apparatus 1 according to a first embodiment of the present invention.

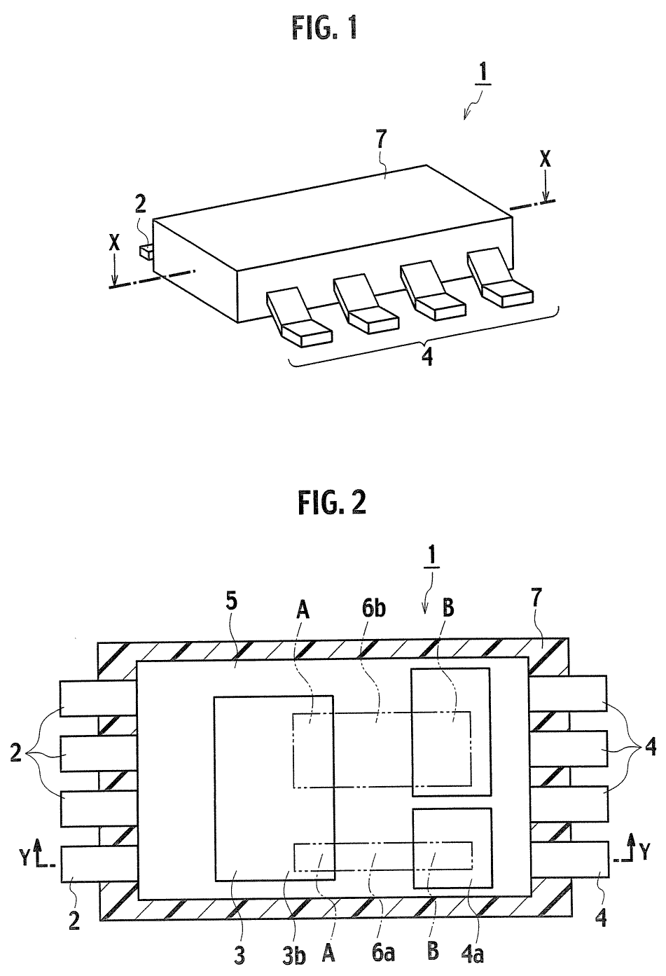

FIG. 1 shows, in a perspective view, an entirety of the semiconductor apparatus 1. The semiconductor apparatus 1 is provided with an enclosure 7 substantially enclosing an entirety of the outside. In this embodiment, the semiconductor apparatus 1 has a first frame of bent leads (referred herein to “first leads”) 2 and a second frame of bent leads (referred herein to “second leads”) 4, four in lead-number respectively, i.e., eight in total number.

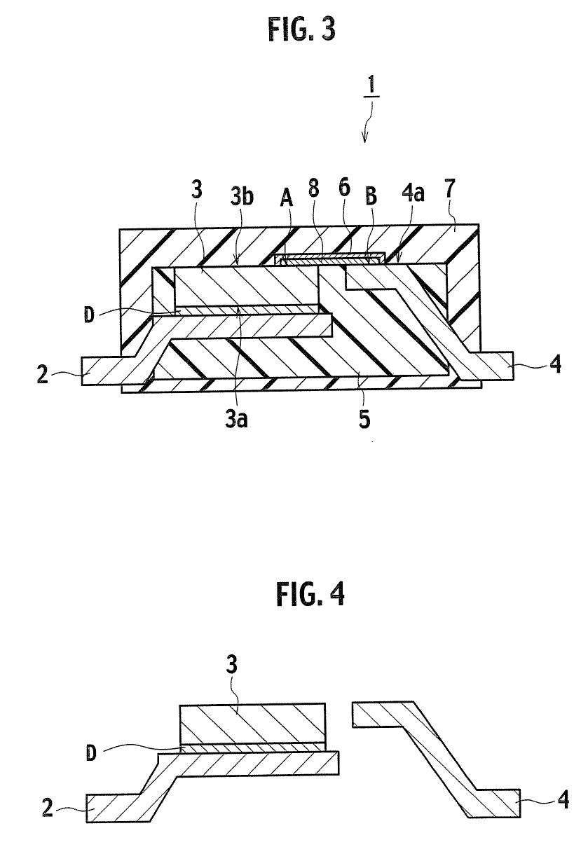

FIG. 2 is a sectional view along line X-X of FIG. 1 of the semiconductor apparatus 1, and FIG. 3, a sectional view along line Y-Y of FIG. 2 of the semiconductor apparatus 1. The first leads 2 and the second leads 4 have their distal end portions oppositely exposed outside at both sides of the enclosure 7. As shown in FIG. 3, the first leads 2 are electrically connected at their proximal end portions, through a conductive die-bond material D thereon, to a semiconductor device 3 as a die.

In other words, the semiconductor device 3 has: a set of drain electrodes arranged on a downside 3a thereof and electrically connected through the die-bond material D to the first leads 2; and a set of gate and source electrodes (referred herein sometimes collectively to “first electrodes”) A arranged on an upside (referred herein sometimes to “obverse side”) 3b opposing the downside 3a, and defined by boundaries of their regions (not depicted). The second leads 4 have their proximal ends incorporated inside the enclosure 7. These proximal ends have upsides thereof (referred herein sometimes to “obverse sides”) 4a, where lead electrodes (referred herein sometimes to “second electrodes”) B are provided.

The obverse side 3b of the semiconductor device 3 and the obverse sides 4a of the second leads 4 have a preset identical height. In other words, in a process where the second leads 4 are bent, their heights are adjusted so that the obverse side 3b of the semiconductor device 3 mounted on the first leads 2 and the obverse sides 4a of the second leads 4 become flush with each other.

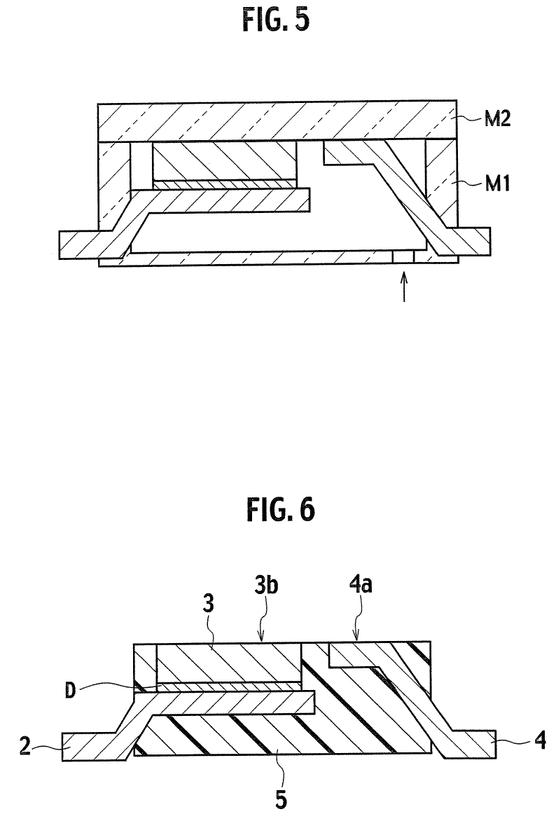

Further, a resin member 5 (referred herein sometimes simply to “resin”) 5 is molded by injecting a molten rein into, filling therewith, a cavity of a shape defined by a later-described mold (refer to FIG. 5), the first leads 2, the semiconductor device 3, and the second leads 4. This resin 5 also is formed to have an identical height to the obverse side 3b and the obverse sides 4a. By such formation of the resin 5, as shown in FIG. 3, the obverse side 3b of the semiconductor device 3 and the obverse sides 4a of the second leads 4 get flush with an obverse side of the resin 5.

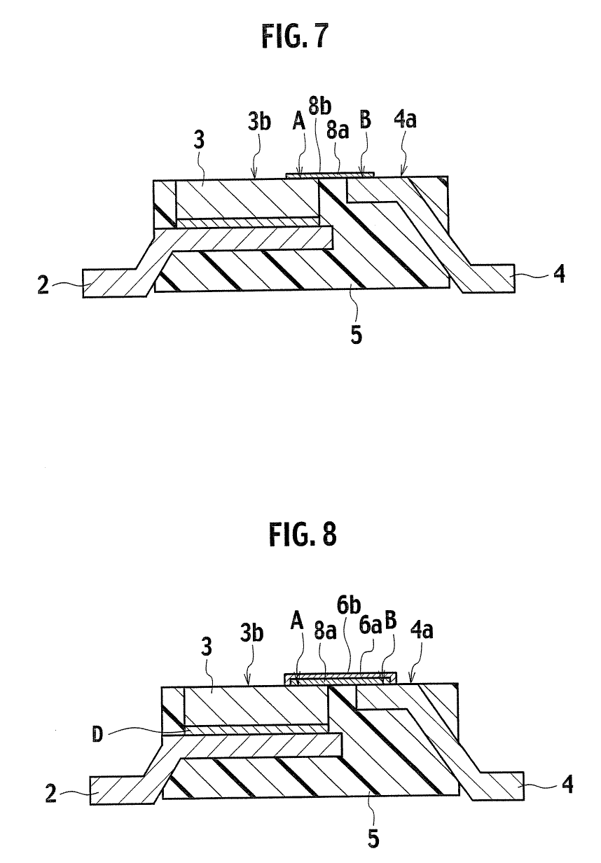

The first electrodes A provided on the obverse side 3b of the semiconductor device 3 and the second electrodes B provided on the obverse sides 4a of the second leads 4 are connected with each other by thin layers of conductive paste 8 coated therebetween. More specifically, a gate-oriented conductive paste layer 8a (refer to FIG. 7) interconnects a gate electrode region, which constitutes one first electrode A of the semiconductor device 3, and a corresponding one of second electrodes B, and a source-oriented conductive paste layer 8b interconnects a source electrode region, which constitutes the other first electrode A of the semiconductor device 3, and the other second electrode B. As used herein, the gate-oriented conductive paste layer 8a and the source-oriented conductive paste layer 8b, as well as the thin layers of conductive paste 8, are referred sometimes to “conductive paste layers 8” or simply to “conductive paste 8”. The conductive paste layers 8a and 8b are covered from above by metallic films (or skins) 6a and 6b (referred herein sometimes collectively to “metallic films 6”), respectively. The resin 5, conductive paste 8, and metallic films 6, as well as the semiconductor device 3 and corresponding portions of the leads 2 and 4, are enclosed by the enclosure 7.

Description is now made of a fabrication method of the semiconductor apparatus 1 according to the first embodiment, with reference to FIG. 4 to FIG. 8.

First, as shown in FIG. 4, the semiconductor device 3 is bonded through the die-bond material D onto the first leads 2, which are bent to have inclined parts, respectively. The second leads 4 are bent, with longer inclined parts than the first leads 2, for the obverse sides 4a to have an identical height to the obverse side 3a of the semiconductor device 3 when placed in position. The first leads 2 and the second leads 4 are to be arranged in opposite positions.

Next, as shown in FIG. 5, the leads 2, 4 and the semiconductor device 3 bonded thereon are set inside a mold M, into arrangement shown in FIG. 4, with a cavity left in between to be filled with a molten resin. The mold M is made as a combination of a vessel-shaped lower mold M1, which has a hole formed as a runner through the bottom for injection of resin, and a lid-shaped upper mold M2, which is put on the lower mold M1. As the upper mold M2 is put on the lower mold M1, the semiconductor device 3 and the second leads 4 set in the mold M have the obverse side 3b and the obverse sides 4a closely contacting a downside of the upper mold M2. Under this condition, molten resin is injected through the hole at the bottom of lower mold M1. Injected mold fills up the cavity defined by the mold M, the first leads 2 with the semiconductor device 3 bonded thereon, and the second leads 4. It is noted that the resin may be any type that is suitable in consideration of characteristics of the semiconductor device 3.

FIG. 6 shows a section of a work after the resin molding, as the mold M is removed. In the molding shown in FIG. 5, where the obverse side 3b of the semiconductor device 3 and the obverse sides 4a of the second leads 4 are brought into close contact with the upper mold M2, molten resin is kept from invading between the upper mold M2 and those obverse sides 3a and 4a. Therefore, when the mold M is removed, as shown in FIG. 6, the resin member 5 has an obverse side thereof exposed between the obverse side 3b and the obverse sides 4a, constituting, together with these obverse sides 3a and 4a, a single continuous plane.

Next, as shown in FIG. 7, over corresponding regions on the obverse side 3b of the semiconductor device 3, the obverse sides 4a of the second leads 4, and the obverse side of the resin member 5 constituting the single plane, the conductive paste layers 8a and 8b are coated in forms, and heated to be thermally set. Over the resin member 5, which is molded with the obverse side constituting a single plane together with the obverse sides 3b and 4a, it is ensured for any part of conductive paste 8 coated thereon to be prevented from falling between the semiconductor device 3 and the second leads 4. Accordingly, conductive paste 8 is coated flat over the coating regions on the single plane, as if it was coated on a planer member. The conductive paste layers 8a and 8b serve for respective electrical connections between the first electrodes A provided on the obverse side 3b of the semiconductor device 3 and the second electrodes B provided on the obverse sides 4a of the second leads 4. The coating of conductive paste may be implemented by a suitable method, such as a dispensing method, screen-printing method, or transfer method. The conductive paste layers 8a and 8b may have arbitrary conductivity and thermosetting conditions so far as they permit a formation of metallic films 6 described later.

Next, as shown in FIG. 8, metallic films 6a and 6b are formed to conformally fit on the conductive paste layers 8a and 8b as cores, respectively. In consideration of conductivity of the conductive paste that has a greater resistance than films of metal, the metallic films 6a and 6b are fit thereon for better electrical connections between the first electrodes A provided on the obverse side 3b of the semiconductor device 3 and the second electrodes B provided on the obverse sides 4a of the second leads 4. In this embodiment, for formation of the metallic films 6a and 6b, plating currents are conducted through corresponding regions of the second electrodes B of the second leads 4, the conductive paste layers 8a and 8b, and the first electrodes A of the semiconductor device 3, thereby plating thereon desirable quantities of metal. The metal to be plated may preferably be low of volume resistivity, such as gold (Au), silver (Ag), or copper (Cu).

The metallic films 6 may be formed by any suitable method else, e.g., an electrolytic plating, non-electrolytic plating, spattering, vapor deposition, or coating. Further, the plating may be deposited thick over lengths of the metallic films 6 or at end portions thereof (for example, at their ends on the first electrodes A of the semiconductor device 3), thereby increasing current conduction areas of surface parts or sectional areas of end portions of the metallic films, thus having the more reduced skin resistances or contact resistances of current conducting paths, to thereby reduce an entirety of connection resistances between the first electrodes A and the second electrodes B. It is noted that the metallic films 6 may preferably have a thickness within a range of, e.g., 1 μm to several μm, in consideration of the conductive currents to be increased in proportion thereto.

Next, the enclosure 7 is attached. In this embodiment, the work shown in FIG. 8 is set in an unshown mold, where molten resin is filled, to thereby mold an enclosure 7 covering the resin member 5. For the enclosure 7, any kind of resin may be employed so far as it is suitable in consideration of characteristics of the semiconductor device 3. The enclosure 7 may be shaped in an arbitrary form subject to a protective coverage over essential current conducting path portions including the metallic films 6 and the first electrodes A and the second electrodes B, and hence the resin member 5 may be partially exposed outside the enclosure 7. The semiconductor apparatus 1 shown in FIG. 1 is fabricated through the foregoing processes.

In other words, the semiconductor apparatus 1 according to the first embodiment is made up by a semiconductor device 3 mounted and bonded on first leads 2, first electrodes A provided on the semiconductor device 3, second leads 4 provided with second electrodes B, a resin member 5 including a portion extending between the semiconductor device 3 and the second leads 4, conductive paste layers 8 and metallic films 6 for electrically interconnecting the first electrodes A and the second electrodes B, and an enclosure 7 as a sealing resin member covering essential portions including proximal ends of the first leads 2, the semiconductor device 3, essential portions including proximal ends of the second leads 4, the resin member 5, the conductive paste layers 8, and the metallic films 6.

According to the first embodiment, the resin member 5 is molded between the semiconductor device 3 and the second leads 4 so as to constitute a single plane together with (the first electrodes A on) an obverse side 3b of the semiconductor device 3 and (the second electrodes B on) obverse sides 4a of the second leads 4, and the first electrodes A and the second electrodes B are electrically connected with each other by the metallic films 6, whereby the internal resistance is allowed to be the more reduced, allowing for an ensured high reliability and facilitated fabrication.

### Second Embodiment

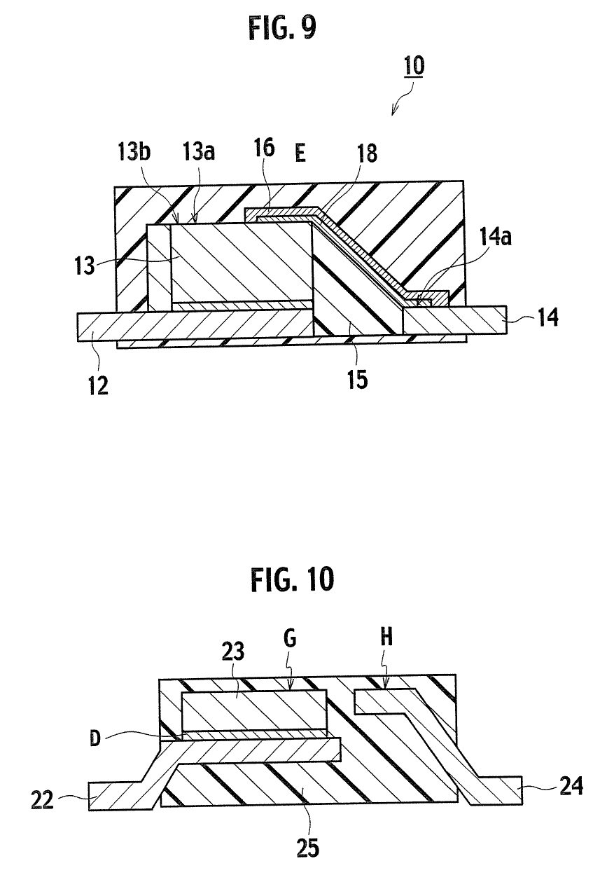

Description is now made of a second embodiment of the present invention, with reference to FIG. 9.

FIG. 9 is a sectional view of a semiconductor apparatus 10 according to the second embodiment. In the semiconductor apparatus 1 according to the first embodiment, the first electrodes A of the semiconductor device 3, which is mounted on the first leads 2 having inclined parts, and the second electrodes B, which are provided on the second leads 4 having longer inclined parts, are both flush with the obverse side of the resin member 5.

To this point, in the semiconductor apparatus 10 according to the second embodiment, a first frame of leads 12 and a second frame of leads 14 are both flat and parallel to each other. Accordingly, gate and source electrodes (referred herein collectively to “first electrodes E”), which are provided on a horizontal obverse side 13b of a semiconductor device 13 bonded on the first leads 12 (and correspond to the first electrodes A in the first embodiment), have a height relative to bottoms of the first leads 12, and lead electrodes (referred herein to “second electrodes F”), which are provided on horizontal obverse sides 14a of the second leads 14 (and correspond to the second electrodes B in the first embodiment), have a height relative to bottoms of the second leads 14, this height being different from that height.

As shown in FIG. 9, a molded resin member 15 has an inclined obverse side thereof extending between the obverse side 13b of the semiconductor device 13, where the first electrodes E are provided, and the obverse sides 14a of the second leads 14, where the second electrodes F are provided, so that the obverse side of the resin member 15 cooperates with the obverse side 13b of the semiconductor device 13 and the obverse sides 14a of the second leads 14 to constitute a connected plane. For electrical connections between the first electrodes E and the second electrodes F, conductive paste layers 18 and metallic films 16 are formed, which also inclined along the obverse side of the resin member 15, and extend between the first electrodes E and the second electrodes F.

According to the second embodiment, the resin member 15 is molded between the semiconductor device 13 and the second leads 14 so as to connect the first electrodes E and the second electrodes F, and the first electrodes E and the second electrodes F are electrically connected with each other by the metallic films 16, whereby even with a height difference between the first electrodes E and the second electrodes F the internal resistance is allowed to be the more reduced, allowing for an ensured high reliability and facilitated fabrication.

### Third Embodiment

Description is now made of a third embodiment of the present invention, with reference to FIG. 10 to FIG. 14.

In the first embodiment, the semiconductor device 3 bonded on the first leads 2 and the second leads 14 are set in the mold M, where molten resin is filled. The semiconductor device 3 and the second leads 4 have their obverse sides 3b and 4a closely contacting the upper mold M2, thereby preventing the resin from invading therebetween, while molding the resin member 5 to have an obverse side thereof constituting a single plane together with the first electrodes A of the semiconductor device 3 and the second electrodes B of the second leads 4.

Some semiconductor apparatuses may include a combination of a semiconductor device and a second frame of leads unable to have their obverse sides closely contacting an upper frame, thus admitting molten resin filling therebetween. The third embodiment describes a fabrication method of such a semiconductor apparatus 20 (refer to FIG. 14).

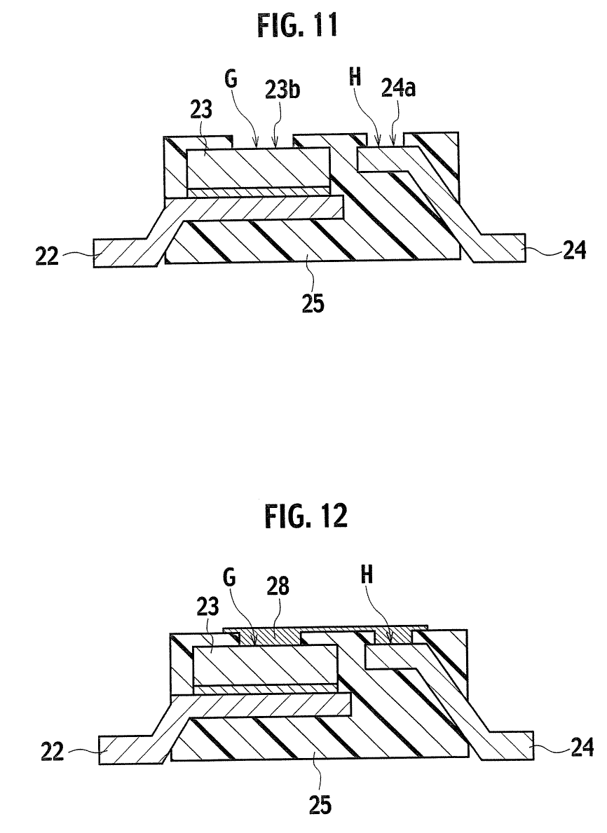

FIG. 10 is a sectional view of a work in a fabrication process of the semiconductor apparatus 20, where a resin member 25 is molded integrally with a first frame of leads 22, a semiconductor device 23 bonded thereon through a die-bond D, and a second frame of leads 24, and a mold M therefor is removed. In this situation, gate and source electrodes (referred herein collectively to “first electrodes G”), which are provided on the semiconductor device 23 (and correspond to the first electrodes A in the first embodiment), and lead electrodes (referred herein to “second electrodes H”), which are provided on the second leads 14 (and correspond to the second electrodes B in the first embodiment), are covered by corresponding parts of the resin member 25, and need to be exposed. Therefore, those regions on an obverse side 23b of the semiconductor device 23, where the first electrodes G are provided, and those regions on obverse sides 24a of the second leads 24, where the second electrodes H are provided, are exposed as shown in FIG. 11 by irradiating resin portions located thereabove, with, e.g., a laser, to thereby remove unnecessary resin. The resin member 25 thus has open cavities formed in an obverse side thereof, where the first electrodes G and the second electrodes H are exposed. It is noted that the areas of regions to be exposed may be set in dependence on desirable currents to be conducted therethrough.

Next, as shown in FIG. 12, the first electrodes G and the second electrodes H are electrically connected with each other by conductive paste layers 28. Each conductive paste layer 28 by end portions that backfill corresponding open cavities, contacting the first electrodes G and the second electrodes H, and a connecting portion that interconnects them, covering a corresponding region on the obverse side of the resin member 25, while the end portions and the connecting portion have their upsides constituting a single continuous plane. The conductive paste layers 28 may be formed by coating a conductive paste by a printing or any suitable method else.

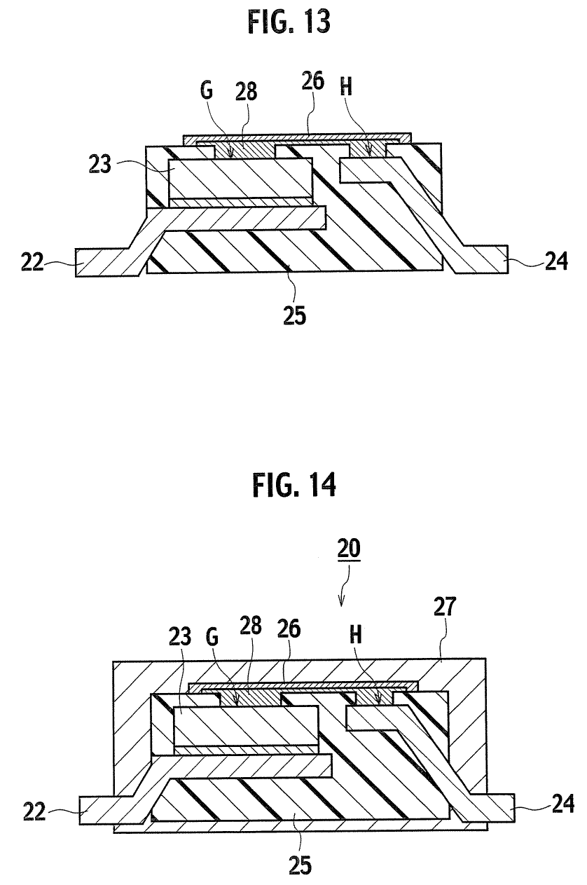

Next, as shown in FIG. 13, metallic films 26 are formed to conformally fit on the conductive paste layers 28 as cores, for electrical connections between the first electrodes G and the second electrodes H. For the metallic films 26, the metal to be used may preferably be low of volume resistivity, and capable of deposition by plating, such as gold (Au), silver (Ag), or copper (Cu). The metallic films 26 may be formed by any suitable method else, e.g., an electrolytic plating, non-electrolytic plating, spattering, vapor deposition, or coating. Further, the plating may be deposited thick over lengths of the metallic films 26 or at end portions thereof (for example, at their ends on the first electrodes G), thereby increasing current conduction areas of surface parts or sectional areas of end portions of the metallic films, thus having the more reduced skin resistances or contact resistances of current conducting paths, to thereby reduce an entirety of connection resistances between the first electrodes G and the second electrodes H. The semiconductor apparatus 20 shown in FIG. 14 is fabricated through the foregoing processes.

According to this embodiment, respective regions of first electrodes G and second electrodes H can be exposed through corresponding open cavities. And, by formation of metallic films 26 electrically interconnecting the first electrodes G and the second electrodes H, the internal resistance is allowed to be the more reduced, allowing for an ensured high reliability and facilitated fabrication.

It is noted that the present invention is not restricted to the foregoing embodiments as they are, and may be implemented with changes to their components without departing from the scope of appended claims. Further, those components disclosed in the foregoing embodiments may be adequately combined. For example, some components of an embodiment may be eliminated, or components of embodiments may be combined.

While preferred embodiments of the present invention have been described using specific terms, such description is for illustrative purposes, and it is to be understood that changes and variations may be made without departing from the spirit or scope of the following claims.

What is claimed is:

1. A semiconductor apparatus comprising:
a semiconductor device provided with a first electrode;
a lead having a second electrode; and
a metallic film electrically interconnecting the first electrode and the second electrode.

2. The semiconductor apparatus as claimed in claim 1, wherein the first electrode, the second electrode, and a surface of resin filled therebetween have an identical height, and are flush with each other.

3. The semiconductor apparatus as claimed in claim 1, wherein the first electrode and the second electrode have different heights, and a surface of resin filled therebetween is inclined to extend between the first electrode and the second electrode.

4. The semiconductor apparatus as claimed in claim 1, wherein the metallic film is made by a plating.

5. The semiconductor apparatus as claimed in claim 2, wherein the metallic film is made by a plating.

6. The semiconductor apparatus as claimed in claim 3, wherein the metallic film is made by a plating.

7. The semiconductor apparatus as claimed in claim 1, wherein the metallic film is made by a vapor deposition.

8. The semiconductor apparatus as claimed in claim 2, wherein the metallic film is made by a vapor deposition.

9. The semiconductor apparatus as claimed in claim 3, wherein the metallic film is made by a vapor deposition.

10. The semiconductor apparatus as claimed in claim 1, wherein the metallic film is made by a spattering.

11. The semiconductor apparatus as claimed in claim 2, wherein the metallic film is made by a spattering.

12. The semiconductor apparatus as claimed in claim 3, wherein the metallic film is made by a spattering.

13. The semiconductor apparatus as claimed in claim 1, wherein the metallic film is made by a coating.

14. The semiconductor apparatus as claimed in claim 2, wherein the metallic film is made by a coating.

15. The semiconductor apparatus as claimed in claim 3, wherein the metallic film is made by a coating.

16. The semiconductor apparatus as claimed in claim 1, comprising a conductive paste coated under the metallic film.

17. The semiconductor apparatus as claimed in claim 2, comprising a conductive paste coated under the metallic film.

18. The semiconductor apparatus as claimed in claim 3, comprising a conductive paste coated under the metallic film.

19. A fabrication method of a semiconductor apparatus comprising the steps of:
filling a resin between a first electrode provided on a semiconductor device and a lead having a second electrode; and
providing a metallic film electrically interconnecting the first electrode and the second electrode, with the filled resin in between.

20. A fabrication method of a semiconductor apparatus comprising the steps of:
filling a resin between a first electrode provided on a semiconductor device and a lead having a second electrode;
removing filled resin parts on the semiconductor device and the lead, having the first electrode and the second electrode exposed respectively; and
providing a metallic film electrically interconnecting the first electrode and the second electrode, with a filled rein part in between.
